(19) United States
(12) Patent Application Publication
(10) Pub. No.: US 2007/0054438 A1
(43) Pub. Date: Mar. 8, 2007

(54) Carrier-free semiconductor package with stand-off member and fabrication method thereof

(75) Inventors: Chien Ping Huang, Taichung Hsien (TW); Fu-Di Tang, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/505,787

(22) Filed: Aug. 16, 2006

(30) Foreign Application Priority Data
Sep. 6, 2005 (TW) 094130494

(51) Int. Cl. H01L 21/00

(52) U.S. Cl. 438/106; 438/126; 438/124; 438/121; 438/108

(57) ABSTRACT

A carrier-free semiconductor package with a stand-off member and a fabrication method thereof are proposed. A carrier with a recessed portion and a plurality of electrical contacts on a surface of the carrier is provided. At least one chip is mounted to the recessed portion of the carrier and is electrically connected to the electrical contacts. An encapsulant is formed on the carrier, for encapsulating the recessed portion, the chip, and the electrical contacts. Finally, the carrier is removed such that the semiconductor package with the stand-off member protruded from a bottom surface thereof is formed. The stand-off member is used for maintaining a predetermined mounting distance between the semiconductor package and an external device, such that problems in the prior art such as reduced fatigue lifetime and cracks of solder joints due to concentration of thermal stress on the solder joints can be overcome in the present invention.

### FIELD OF THE INVENTION

The present invention relates to packaging technologies for semiconductor chips, and more particularly, to a carrier-free semiconductor package with a stand-off member, and a fabrication method of the semiconductor package.

### BACKGROUND OF THE INVENTION

Conventional semiconductor packages usually use a lead frame as a chip carrier, such as quad flat package (QFP), quad flat non-leaded (QFN) package, small outline package (SOP) and dual in-line package (DIP). To improve the heat dissipating efficiency of the semiconductor package and fulfill the requirement of chip scale package (CSP), the QFN package with a bottom surface of a die pad being exposed or an exposed-pad semiconductor package has become widely adopted.

For the QFN semiconductor package, bottom surfaces of the die pad and leads are all exposed from an encapsulant used for encapsulating a semiconductor chip, such that the semiconductor package can be electrically connected an external device (such as a printed circuit board) directly via the exposed surfaces of the leads by means of a solder material. The semiconductor chip is mounted on the die pad and is electrically connected to the leads via bonding wires, such that heat produced by the semiconductor chip can be effectively transmitted out of the semiconductor package through the exposed surface of the die pad. Due to no outer leads being provided, the QFN semiconductor package can be made compact in size.

However, considering an increasing requirement in profile miniaturization, the lead frame with a certain thickness used in the QFN semiconductor package may cause a limitation on further reducing the height of the semiconductor package. Accordingly, a carrier-free semiconductor package has been proposed, which reduces the thickness of the lead frame and thus has a smaller profile than a conventional lead-frame-based semiconductor package. The related prior arts include U.S. Pat. No. 5,830,800, U.S. Pat. No. 6,072,239 and Taiwanese Patent No. 1229432.

FIG. 1 shows a carrier-free semiconductor package 1 disclosed by U.S. Pat. No. 5,830,800. To fabricate the carrier-free semiconductor package 1, a plurality of electroplated pads 11 with a thickness of about 6 μm are formed in advance on a copper carrier (not shown), wherein each of the electroplated pads 11 comprises Au/Pd/Ni/Pd (gold/palladium/nickel/palladium) layers. Then, a semiconductor chip 12 is mounted on the copper carrier and is electrically connected to the electroplated pads 11 by bonding wires 13. A molding process is performed to form an encapsulant 14. Subsequently, the copper carrier (not shown) is removed such that the electroplated pads 11 are exposed from the encapsulant 14, and the carrier-free semiconductor package 1 is thus obtained. Solder joints 15 can be further formed on the exposed electroplated pads 11 by a solder material, so as to allow the electroplated pads 11 of the semiconductor package 1 to be electrically connected to bond pads 17 on a printed circuit board 16 directly via the solder joints 15.

However, as the semiconductor package 1 is mounted to the printed circuit board 16 by surface mount technology (SMT) via the solder joints 15 formed of the solder material through a reflow process, if an amount of the solder material being used is not controlled accurately, especially in the case that a mounting distance between the semiconductor package 1 and the printed circuit board 16 is not properly controlled, it may cause contact between the adjacent solder joints and thereby lead to a short circuit problem.

Moreover, since the semiconductor package 1 and the printed circuit board 16 are made of different materials with different coefficients of thermal expansion (CTEs), thermal stress is produced and applied to the solder joints 15, wherein the thermal stress is proportional to mismatch in CTE between the semiconductor package 1 and the printed circuit board 16 and is inversely proportional to the height of the solder joints 15. That is, the thermal stress is proportional to ((α²−α₁)ΔTδ₁)/h, where (α²α₁) represents the mismatch in CTE between the semiconductor package 1 and the printed circuit board 16, ΔT represents the maximal temperature difference between the semiconductor package 1 and the printed circuit board 16, δ₁ represents the distance from the center of the semiconductor package 1 to the farthest solder joint 15, and h represents the height of the solder joints 15. If the height h of the solder joints 15 is very small, accordingly very large thermal stress would be produced and exerted to the solder joints 15. This situation not only reduces the fatigue life of the solder joints 15 but also may cause cracks of the solder joints 15, thereby adversely affecting the product reliability. On the other hand, if the amount of the solder material and the height h of the solder joints 15 are increased, the short circuit problem may occur between the adjacent solder joints due to the use of too much solder material or improper control of the mounting distance between the semiconductor package 1 and the printed circuit board 16.

To overcome the above drawbacks, U.S. Pat. No. 6,072,239 discloses a carrier-free semiconductor package 2 as shown in FIG. 2, which is fabricated by the following steps. First, a plurality of recessed electroplated pads 21 are formed on a copper carrier (not shown) and are electrically connected to a semiconductor chip 23 via a plurality of bonding wires 22. Then, the semiconductor chip 23 and the plurality of bonding wires 22 are encapsulated by an encapsulant 24. Finally, the copper carrier is removed such that the plurality of recessed electroplated pads 21 are protruded and exposed from the encapsulant 24.

The protruded and exposed recessed electroplated pads 21 may serve as a stand-off member for the semiconductor package 2 to reduce concentration of the thermal stress and prevent the problems such as reduced fatigue life and cracks of the solder joints. However, as the solder joints would be formed under the recessed electroplated pads 21 or the stand-off member, short circuit is still likely to occur in case the amount of the solder material or the mounting distance is not properly controlled as discussed above. Moreover, the use of the recessed electroplated pads 21 leads to the need of longer bonding wires (such as gold wires) 22 and a more complicated and time-consuming electroplating process, thereby undesirably increasing the fabrication cost of the semiconductor package 2. In addition, since the recessed electroplated pads 21 are protruded from the encapsulant 24 and the solder joints are formed under the protruded electroplated pads 21, the overall height of the semiconductor package 2 is increased, which is not in favor of profile miniaturization.

Taiwanese Patent No. 1229432 discloses a carrier-free semiconductor package similar to that of U.S. Pat. No. 6,072,239. This semiconductor package is formed with a plurality of recessed portions in which an encapsulant is filled. However, the recessed portions are not actually protruded from a bottom surface of the semiconductor package and thus do not serve as a stand-off member.

Therefore, the problem to be solved here is to provide a carrier-free semiconductor package, which can effectively resolve the foregoing drawbacks.

### SUMMARY OF THE INVENTION

In light of the above drawbacks of the prior art, an objective of the present invention is to provide a carrier-free semiconductor package with a stand-off member and a fabrication method thereof, which can improve the reliability of the semiconductor package.

Another objective of the present invention is to provide a carrier-free semiconductor package with a stand-off member and a fabrication method thereof, which can reduce the thickness of the semiconductor package.

A further objective of the present invention is to provide a carrier-free semiconductor package with a stand-off member and a fabrication method thereof, which can fix a mounting distance between the semiconductor package and an external device.

To achieve the above and other objectives, the present invention proposes a carrier-free semiconductor package with a stand-off member, which can be mounted to an external device. The carrier-free semiconductor package comprises a plurality of electrical contacts; at least one chip electrically connected to the electrical contacts; an encapsulant for encapsulating the chip and the electrical contacts, wherein at least one surface of each of the electrical contacts is exposed from the encapsulant; and the stand-off member protruded from a bottom surface of the encapsulant and corresponding in position to the chip, the stand-off member having a predetermined height difference from the electrical contacts, so as to maintain a predetermined mounting distance between the semiconductor package and the external device.

The carrier-free semiconductor package may further comprise a plurality of electrically connecting elements for electrically connecting the chip to the electrical contacts, wherein the electrically connecting elements can be bonding wires formed by a wire-bonding process or metal bumps used in a flip-chip fabrication process. The stand-off member can be larger than or equal to the chip in size. The stand-off member may comprise a die pad where the chip is mounted, and a thermally conductive resin layer with/without electrical conductivity between the chip and the die pad.

The present invention also proposes a method for fabricating the above carrier-free semiconductor package, comprising the steps of: providing a carrier having a recessed portion and a plurality of electrical contacts on a surface of the carrier; mounting at least one chip to the recessed portion of the carrier, and electrically connecting the chip to the electrical contacts; forming an encapsulant on the carrier, for encapsulating the recessed portion, the chip and the electrical contacts; and removing the carrier such that a stand-off member protruded from a bottom surface of the encapsulant is formed and the electrical contacts are exposed.

In a preferred embodiment, an etching process can be performed to form the recessed portion on the surface of the carrier (such as a copper plate). Further, an electroplating process can be performed to form the plurality of electrical contacts on the surface of the carrier and a die pad in the recessed portion. The chip can be electrically connected to the electrical contacts by a wire-bonding process or a flip-chip process. The stand-off member is located under the chip, and has a size larger than or equal to that of the chip.

To achieve the above and other objectives, the present invention further proposes a carrier-free semiconductor package with a stand-off member, which can be mounted to an external device. The carrier-free semiconductor package comprises a plurality of electrical contacts; at least one chip electrically connected to the electrical contacts; an encapsulant for encapsulating the chip and the electrical contacts, wherein at least one surface of each of the electrical contacts is exposed from the encapsulant; and a first stand-off member protruded from a bottom surface of the chip and having a predetermined height difference from the electrical contacts, so as to maintain a predetermined mounting distance between the semiconductor package and the external device. The first stand-off member can comprise a die pad corresponding in position to the bottom surface of the chip, and a resin layer filled between the chip and the die pad. The size of the first stand-off member may be smaller than, equal to or larger than that of the chip. The carrier-free semiconductor package can further comprise a second stand-off member protruded from a bottom surface of the encapsulant and located between the electrical contacts and the chip. The second stand-off member may comprise a continuous ring structure, a discontinuous strip structure or a discontinuous dot structure.

The present invention also proposes a method for fabricating the above carrier-free semiconductor package, comprising the steps of: providing a carrier having a recessed portion on a surface thereof; forming a plurality of electrical contacts on the surface of the carrier and a die pad in the recessed portion of the carrier; applying a resin layer on the die pad in the recessed portion of the carrier; mounting at least one chip to the resin layer corresponding in position to the die pad in the recessed portion of the carrier, and electrically connecting the chip to the electrical contacts; forming an encapsulant on the carrier, for encapsulating the chip and the electrical contacts; and removing the carrier such that a first stand-off member protruded from a bottom surface of the chip is formed and the electrical contacts are exposed. In a preferred embodiment, an etching process can be performed to form the recessed portion on the surface of the carrier (such as a copper plate), and an electroplating process can be performed to form the electrical contacts on the surface of the carrier and the die pad in the recessed portion. The chip can be attached to the resin layer by an adhesive (such as silver paste or a non-electrically conductive adhesive). Moreover, the chip can be electrically connected to the electrical contacts by a wire-bonding process or a flip-chip process. The first stand-off member is located under the chip, and may have a size smaller than, equal to or larger than that of the chip. A second stand-off member can further be formed between the electrical contacts and the chip and protruded from a bottom surface of the encapsulant. The second stand-off member may comprise a continuous ring structure, a discontinuous strip structure or a discontinuous dot structure.

### BRIEF DESCRIPTION OF DRAWINGS

The present invention can be more fully understood by reading the following detailed description of the preferred embodiments, with reference made to the accompanying drawings, wherein:

FIG. 1 (PRIOR ART) is a cross-sectional view of a carrier-free semiconductor package according to U.S. Pat. No. 5,830,800;

FIG. 2 (PRIOR ART) is a cross-sectional view of a carrier-free semiconductor package according to U.S. Pat. No. 6,072,239;

FIGS. 3A to 3I are cross-sectional diagrams showing steps of a method for fabricating a carrier-free semiconductor package with a stand-off member according to a first embodiment of the present invention;

FIG. 4 is a cross-sectional diagram showing a structure of the carrier-free semiconductor package according to the present invention being mounted to a printed circuit board;

FIG. 5 is a cross-sectional view of a carrier-free semiconductor package with a stand-off member according to a second embodiment of the present invention;

FIGS. 6A to 6F are cross-sectional diagrams showing steps of a method for fabricating the carrier-free semiconductor package according to the second embodiment of the present invention; and

FIG. 7 is a cross-sectional view of a carrier-free semiconductor package having stand-off members according to a third embodiment of the present invention.

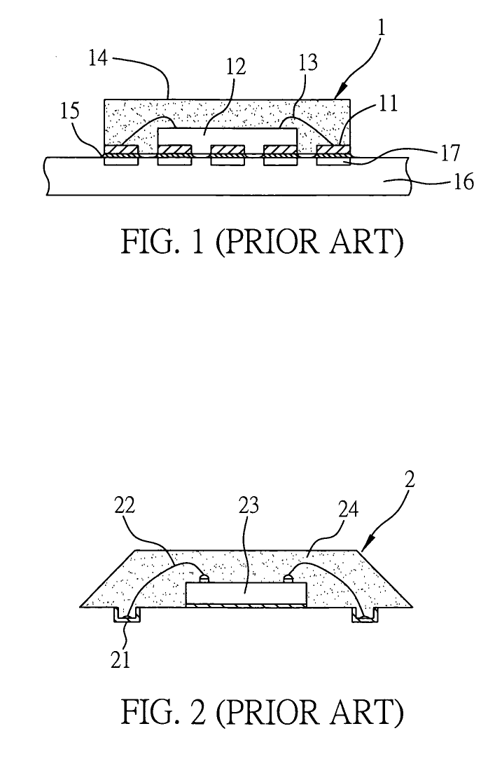

### DETAILED DESCRIPTION OF PREFERRED EMBODIMENTS

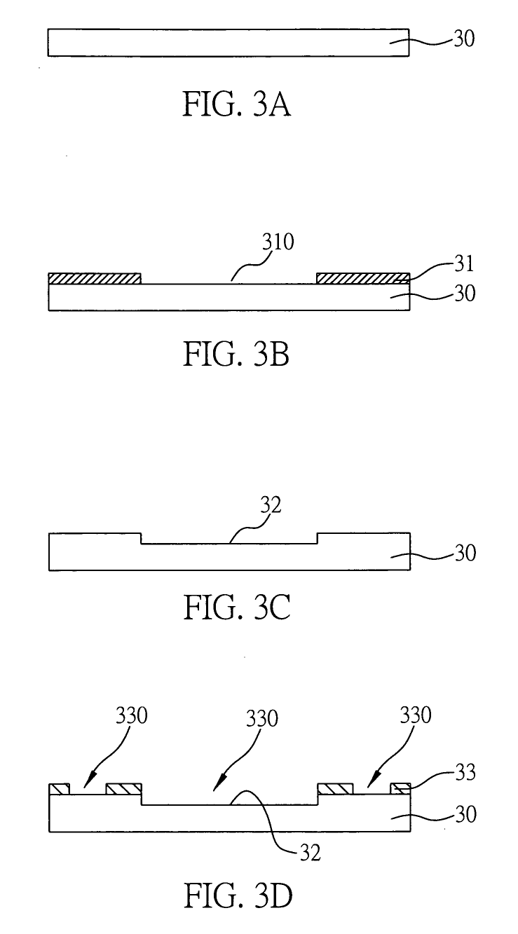

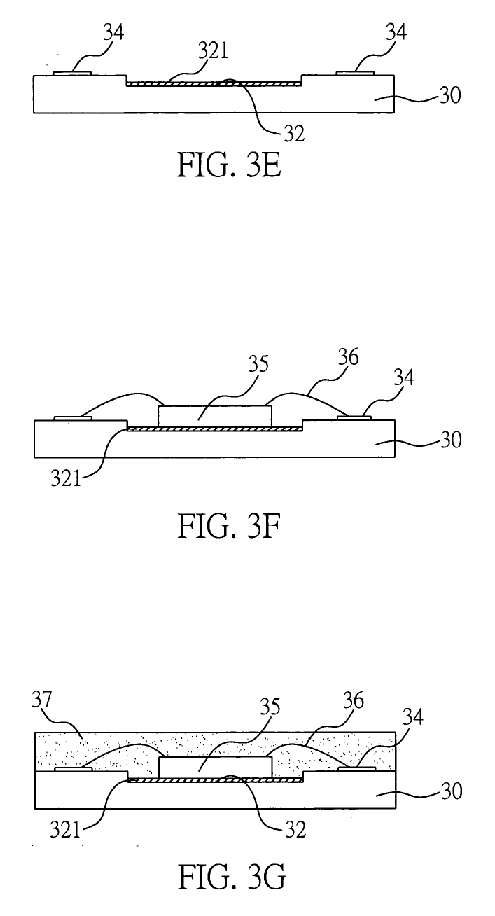

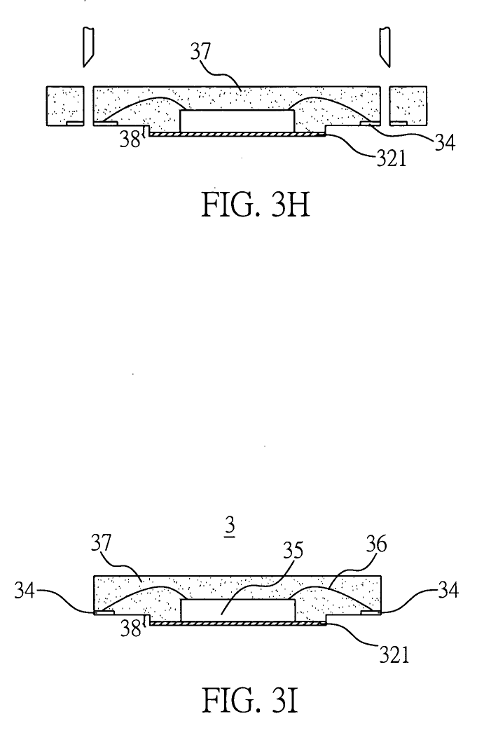

Preferred embodiments of a carrier-free semiconductor package having a stand-off member and a fabrication method thereof as proposed in the present invention are described as follows with reference to FIGS. 3 to 7. It should be noted that the drawings provided here are simplified schematic diagrams only showing relevant components to the present invention, and the component layout could be more complicated in practical implementation.

### First Embodiment

FIGS. 3A to 3I are cross-sectional diagrams showing steps of a method for fabricating a carrier-free semiconductor package with a stand-off member according to a first embodiment of the present invention.

As shown in FIG. 3A, a carrier 30 is provided, which can be made of a metallic material, such as a copper plate. The carrier 30 is used to temporarily carry components of a semiconductor package to be fabricated and also provide a current conductive path for a subsequent electroplating process.

As shown in FIG. 3B, a resist layer 31 is applied on a surface of the carrier 30. The resist layer 31 is patterned to form an opening 310 for exposing a predetermined portion (such as a central position as shown) of the carrier 30. The resist layer 31 can be a photoresist layer, and is subjected to the patterning process such as exposure and development to form the opening 310.

As shown in FIG. 3C, an etching process is performed using the resist layer 31 as a mask so as to form a recessed portion 32 at the predetermined portion of the carrier 30 corresponding to the opening 310 of the resist layer 31. Then, the resist layer 31 is removed. The size of the recessed portion 32 can be larger than or equal to that of a chip that is to be mounted to the carrier 30 according to a requirement of heat dissipation. In this embodiment, the recessed portion 32 is larger in size than the chip.

As shown in FIG. 3D, another resist layer 33 is applied on the surface of the carrier 30. The resist layer 33 is patterned to form a plurality of openings 330 for exposing the recessed portion 32 and predetermined positions of the carrier 30. The resist layer 33 can be a photoresist layer, and is subjected to the patterning process such as exposure and development to form the openings 330.

As shown in FIG. 3E, an electroplating process is performed using the metallic carrier 30 to conduct an electroplating current, so as to form a die pad 321 in the recessed portion 32 and a plurality of electrical contacts 34 at the predetermined positions of the carrier 31, which are exposed via the openings 330 of the resist layer 33, according to a predetermined circuit layout. Then, the resist layer 33 is removed. Each of the electrical contacts 34 can be a thin electroplated pad comprising Au/Ni/Cu/Pd (gold/nickel/copper/palladium) layers, in favor of profile miniaturization for the semiconductor package to be fabricated.

As shown in FIG. 3F, a chip 35 is attached to the die pad 321 by an adhesive such as silver paste (not shown). Then, a wire-bonding process is performed such that a plurality of electrically connecting elements, i.e. bonding wires 36 (such as gold wires), are formed to electrically connect the chip 35 to the electrical contacts 34.

As shown in FIG. 3G, a molding process is performed to form an encapsulant 37 on the carrier 30 so as to encapsulate the chip 35, the bonding wires 36, the electrical contacts 34 and the recessed portion 32, such that the chip 35 and the bonding wires 36 are protected by the encapsulant 37. The encapsulant 37 can be made of a resin material. The encapsulant 37 also encapsulates the die pad 321 in the recessed portion 32.

As shown in FIG. 3H, the carrier 30 is removed by, for example, etching, such that a bottom surface of each of the electrical contacts 34 is exposed from the encapsulant 37 to be capable of having electrical connection with an external device, and a stand-off member 38 is formed by the die pad 321 and a portion of the encapsulant 37, which are formed in the recessed portion 32 as above described. Then, a singulation process can be performed so as to obtain a semiconductor package 3 with the stand-off member 38 and the exposed electrical contacts 34 as shown in FIG. 31.

Therefore, the semiconductor package 3 fabricated by the above method of the present invention comprises a plurality of electrical contacts 34; at least one chip 35 electrically connected to the electrical contacts 34 via a plurality of bonding wires 36; a die pad 321 to which the chip 35 is attached; an encapsulant 37; and a stand-off member 38 formed at a bottom surface of the encapsulant 37 and having a predetermined height difference from the electrical contacts 34, so as to maintain a predetermined mounting distance between the semiconductor package 3 and the external device to which the semiconductor package 3 can be mounted.

Referring to FIG. 4, the semiconductor package 3 can be mounted to the external device such as a printed circuit board 4 via the stand-off member 38, and the electrical contacts 34 of the semiconductor package 3 can be electrically connected to bond pads 40 on the printed circuit board 4 through solder joints 41 by surface mount technology (SMT). Since the stand-off member 38 of the semiconductor package 3 maintains the predetermined mounting distance between the semiconductor package 3 and the printed circuit board 4, problems in the prior art, such as short circuit due to improper control of the mounting distance and large thermal stress or cracks of solder joints due to low height of the solder joints, can be avoided in the present invention. Moreover, the stand-off member 38 may have a predetermined thickness equal to the height of the solder joints 41, and the thickness of the die pad 321 and the thickness of part of the chip 35 are included in the thickness of the stand-off member 38, such that the overall height of the semiconductor package 3 mounted to the printed circuit board 4 can be reduced. In addition, since the chip 35 is lowered in elevation to be partially level with the stand-off member 38, the length of the bonding wires 36 used for electrically connecting the chip 35 to the electrical contacts 34 can be shortened, thereby reducing the fabrication cost of the semiconductor package 3.

It should be noted that besides the electroplated pads, the electrical contacts of the present invention may also be formed as conductive bumps, for example, bump leads on the carrier, which are similarly electrically connected to the chip by the bonding wires. Further, the semiconductor package can be fabricated individually or in a batch-type manner in the present invention.

Besides the wire-bonding process, the chip can also be electrically connected to the electrical contacts by a flip-chip process such as metal bumps in place of the bonding wires serve as the electrically connecting elements. As the flip-chip process is well known in the art, it is not to be further detailed here or illustrated by drawings.

Moreover, the recessed portion of the carrier, as described above, may have a size larger than or equal to that of the chip. Accordingly, the stand-off member having a size corresponding to that of the recessed portion, can thus be larger than or equal to the chip in size.

### Second Embodiment

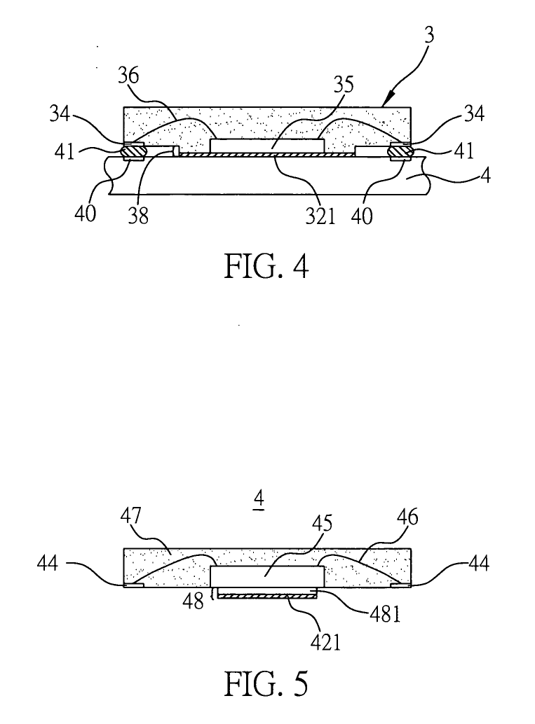

FIG. 5 shows a cross-sectional view of a semiconductor package 4 according to a second embodiment of the present invention. The semiconductor package 4 comprises a plurality of electrical contacts 44; at least one chip 45 electrically connected to the electrical contacts 44 via a plurality of bonding wires 46; a die pad 421 to which the chip 45 can be attached; an encapsulant 47; and a stand-off member 48 formed at a bottom surface of the chip 45 and having a predetermined height difference from the electrical contacts 44. The size of the chip 45 may be larger than that of the stand-off member 48 and that of the die pad 421. The semiconductor package 4 can similarly be mounted to an external device via the stand-off member 48. In order to control and fix the height of the stand-off member 48, a thermally conductive resin layer 481 with/without electrical conductivity can be filled between the chip 45 and the die pad 421.

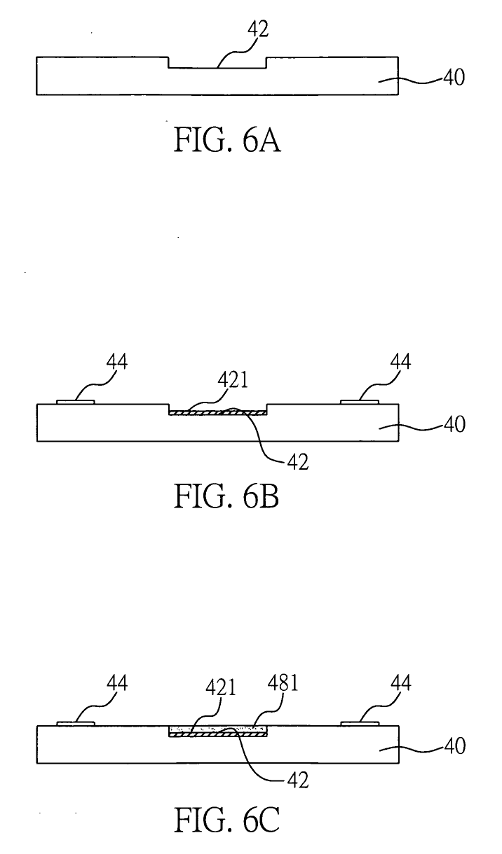

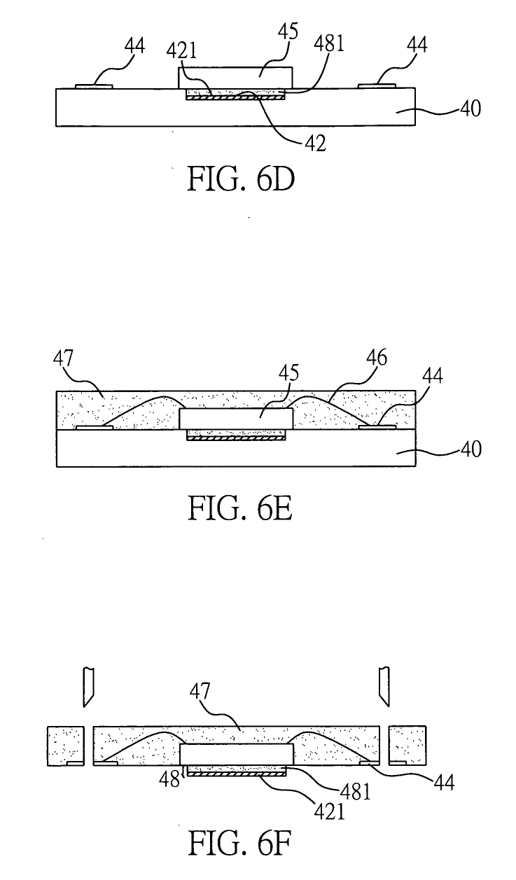

FIGS. 6A to 6F show steps of a fabrication method of the semiconductor package 4 according to the second embodiment of the present invention, and the description thereof focuses on different parts in fabrication from the above fabrication method of the first embodiment, such that the fabrication steps of this embodiment which are same as those in the first embodiment are not further detailed.

As shown in FIG. 6A, a carrier 40 with a recessed portion 42 is provided. The recessed portion 42 can be formed on a surface of the carrier 40 by those processes such as applying a resist layer, patterning, etching and removing the resist layer as described in the above first embodiment.

As shown in FIG. 6B, a plurality of electrical contacts 44 are formed on the surface of the carrier 40 and a die pad 421 is formed in the recessed portion 42. The electrical contacts 44 and the die pad 421 can be formed by processes including applying a resist layer, patterning, performing electroplating and removing the resist layer. Each of the electrical contacts 44 may be a thin electroplated pad comprising Au/Ni/Cu/Pd layers.

As shown in FIG. 6C, a thermally conductive resin layer 481 with/without electrical conductivity is filled in the recessed portion 42 with the die pad 421

As shown in FIG. 6D, a chip 45 is attached to the resin layer 481 corresponding in position to the die pad 421 by an adhesive such as silver paste (not shown), and a wire-bonding process is performed such that a plurality of electrically connecting elements, i.e. bonding wires 46 (such as gold wires), are formed to electrically connect the chip 45 to the electrical contacts 44 around the chip 45.

As shown in FIG. 6E, a molding process is performed to form an encapsulant 47 on the carrier 40, for encapsulating the chip 45, the electrical contacts 44 and the bonding wires 46, so as to protect the chip 45 and the bonding wires 46. The encapsulant 47 can be made of a resin material.

As shown in FIG. 6F, the carrier 40 is removed by, for example, etching, such that a bottom surface of each of the electrical contacts 44 is exposed from the encapsulant 47 to be capable of being electrically connected to an external device, and a stand-off member 48 comprising the die pad 421 and the resin layer 481 is formed and protruded from a bottom surface of the chip 45. Then, a singulation process can be performed to obtain the semiconductor package 4 as shown in FIG. 5.

In this embodiment, the stand-off member smaller in size than the chip is illustrated. Compared with the above first embodiment, this embodiment has primary differences in that the encapsulant does not encapsulate the die pad, and the stand-off member comprises the die pad and the resin layer filled between the die pad and the chip. It should be noted that besides having a size smaller than that of the chip, the stand-off member fabricated by the method of the second embodiment may also be made with a size larger than or equal to that of the chip.

### Third Embodiment

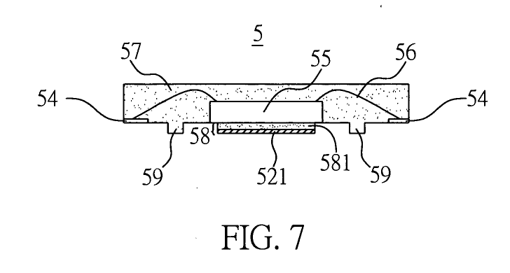

FIG. 7 shows a cross-sectional view of a semiconductor package 5 according to a third embodiment. The third embodiment differs from the above second embodiment in that the semiconductor package 5 further comprises a second stand-off member 59. Particularly, the semiconductor package 5 comprises a plurality of electrical contacts 54; at least one chip 55 electrically connected to the electrical contacts 54 via a plurality of bonding wires 54; a die pad 521 where the chip 55 can be mounted; an encapsulant 57; a first stand-off member 58 formed at a bottom surface of the chip 55 and including the die pad 521 and a resin layer 581 filled between the chip 55 and the die pad 521; and the second stand-off member 59 formed at a bottom surface of the encapsulant 57.

The second stand-off member 59 is protruded from the bottom surface of the encapsulant 57 and is located between the electrical contacts 54 and the chip 55. Preferably, the second stand-off member 59 is formed by a molding process for fabricating the encapsulant 57. The second stand-off member 59 can comprise a continuous ring structure, a discontinuous strip structure or a discontinuous dot structure. The fabrication method of the semiconductor package 5 is similar to that of the semiconductor package 4, with the only difference in additionally forming the second stand-off member 59. To fabricate the second stand-off member, one or more recessed portions predetermined for the second stand-off member are formed on the carrier simultaneously when the recessed portion corresponding to the first stand-off member is formed on the carrier. Then, during the molding process, the resin material used for fabricating the encapsulant is also filled in the one or more recessed portions corresponding to the second stand-off member. Thereby, the second stand-off member is completed after removing the carrier.

Therefore, the carrier-free semiconductor package with the stand-off member and the fabrication method thereof according to the present invention use the stand-off member to maintain the predetermined mounting distance between the semiconductor package and the external device, such that the short circuit problem due to improper control of the mounting distance and the reliability problem caused by large thermal stress or cracks of solder joints due to low height of the solder joints as in the prior art can be prevented in the present invention. Moreover, since the thickness of the stand-off member may be controlled to be equal to the height of the solder joints, and the thickness of the die pad and the thickness of part of the chip are included in the thickness of the stand-off member, the overall height of the semiconductor package mounted to the external device can be reduced. In addition, since the chip is lowered in elevation to be partially level with the stand-off member, the length of the bonding wires used for electrically connecting the chip to the electrical contacts can be shortened, thereby reducing the fabrication cost of the semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A carrier-free semiconductor package capable of being mounted to an external device, comprising:
a plurality of electrical contacts;
at least one chip electrically connected to the electrical contacts;
an encapsulant for encapsulating the chip and the electrical contacts, wherein at least one surface of each of the electrical contacts is exposed from the encapsulant; and
a first stand-off member protruded from a bottom surface of the chip and having a predetermined height difference from the electrical contacts, so as to maintain a predetermined mounting distance between the semiconductor package and the external device.

2. The carrier-free semiconductor package of claim 1, wherein the first stand-off member comprises a die pad corresponding in position to the bottom surface of the chip, and a resin layer filled between the chip and the die pad.

3. The carrier-free semiconductor package of claim 1, further comprising a second stand-off member protruded from a bottom surface of the encapsulant and located between the electrical contacts and the chip.

4. The carrier-free semiconductor package of claim 3, wherein the second stand-off member comprises a continuous ring structure.

5. The carrier-free semiconductor package of claim 3, wherein the second stand-off member comprises a discontinuous strip structure.

6. The carrier-free semiconductor package of claim 3, wherein the second stand-off member comprises a discontinuous dot structure.

7. The carrier-free semiconductor package of claim 1, further comprising a plurality of electrically connecting elements for electrically connecting the chip to the electrical contacts.

8. The carrier-free semiconductor package of claim 7, wherein the electrically connecting elements are bonding wires.

9. The carrier-free semiconductor package of claim 7, wherein the electrically connecting elements are metal bumps.

10. The carrier-free semiconductor package of claim 1, wherein the first stand-off member is smaller in size than the chip.

11. The carrier-free semiconductor package of claim 1, wherein the first stand-off member is equal in size to the chip.

12. A fabrication method of a carrier-free semiconductor chip, comprising the steps of:
providing a carrier having a recessed portion on a surface thereof;
forming a plurality of electrical contacts on the surface of the carrier and a die pad in the recessed portion of the carrier;
applying a resin layer on the die pad in the recessed portion of the carrier;
mounting at least one chip to the resin layer corresponding in position to the die pad in the recessed portion of the carrier, and electrically connecting the chip to the electrical contacts;
forming an encapsulant on the carrier, for encapsulating the chip and the electrical contacts; and
removing the carrier such that a first stand-off member protruded from a bottom surface of the chip is formed and the electrical contacts are exposed.

13. The fabrication method of claim 12, wherein the recessed portion is formed on the surface of the carrier by etching.

14. The fabrication method of claim 12, wherein the die pad in the recessed portion of the carrier and the electrical contacts on the surface of the carrier are formed by electroplating.

15. The fabrication method of claim 12, wherein the chip is attached to the resin layer by an adhesive.

16. The fabrication method of claim 12, wherein the first stand-off member is located under the chip.

17. The fabrication method of claim 12, wherein the first stand-off member is smaller in size than the chip.

18. The fabrication method of claim 12, wherein the first stand-off member is equal in size to the chip.

19. The fabrication method of claim 12, further comprising forming a second stand-off member protruded from a bottom surface of the encapsulant and located between the electrical contacts and the chip.

20. The fabrication method of claim 19, wherein the second stand-off member comprises a continuous ring structure.

21. The fabrication method of claim 19, wherein the second stand-off member comprises a discontinuous strip structure.

22. The fabrication method of claim 19, wherein the second stand-off member comprises a discontinuous dot structure.
